(19) United States
(12) Patent Application Publication
(10) Pub. No.: US 2024/0355578 A1
(43) Pub. Date: Oct. 24, 2024

(54) SOFTWARE, METHODS, AND SYSTEMS FOR DETERMINATION OF A LOCAL FOCUS POINT

(71) Applicant: ASML NETHERLANDS B.V., Veldhoven (NL)

(72) Inventors: Te-Sheng WANG, San Jose, CA (US); Szu-Po WANG, Kaohsiung (TW); Kai-Yuan CHI, Pingtung City (TW)

(73) Assignee: ASML NETHERLANDS B.V., Veldhoven (NL)

(21) Appl. No.: 18/761,319

(22) Filed: Jul. 2, 2024

Related U.S. Application Data
(63) Continuation of application No. PCT/EP2022/087925, filed on Dec. 27, 2022.
(60) Provisional application No. 63/296,572, filed on Jan. 5, 2022.

(51) Int. Cl. H01J 37/22; H01J 37/28

(52) U.S. Cl. CPC H01J 37/222; H01J 37/28

(57) ABSTRACT

Disclosed are non-transitory computer-readable media, systems, and computer-implemented methods that describe obtaining hot spot (HS) location information with respect to a printed pattern; obtaining LFP search criteria for searching the printed pattern to determine a local focus point (LFP) for an imaging device; selecting a HS area in the printed pattern that contains a HS; and determining the LFP proximate to the HS area based on the LFP search criteria, the LFP not containing the HS.

### CROSS-REFERENCE TO RELATED APPLICATIONS

This application claims priority of International application PCT/EP2022/087925, filed on Dec. 27, 2022, which claims priority of U.S. application 63/296,572, filed on Jan. 5, 2022. These applications are incorporated herein by reference in their entireties.

### TECHNICAL FIELD

The description herein relates generally to mask manufacturing and patterning processes. More particularly, the disclosure includes apparatus, methods, and computer programs for a determining a focus location for an imaging device that will not overly damage a printed pattern when imaging a feature that has a narrow process window.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g., comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.”

At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λA/NA, where λ is the wavelength of radiation employed (e.g., 248 nm or 193 nm), NA is the numerical aperture of projection optics in the lithographie projection apparatus, CD is the “critical dimension”-generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

According to some embodiments, there is provided a non-transitory computer-readable medium that stores a set of instructions that is executable by at least one processor of an apparatus to cause the apparatus to perform a method, the method comprising: obtaining hot spot (HS) location information with respect to a printed pattern; obtaining LFP search criteria for searching the printed pattern to determine a local focus point (LFP) for an imaging device; selecting a HS area in the printed pattern that contains a HS; and determining the LFP proximate to the HS area based on the LFP search criteria, the LFP not containing the HS.

In some embodiments, the HS can be a location on the printed pattern that has a higher failure potential than other locations on the printed pattern. Also, the LFP can be an area on the printed pattern that meets the LFP search criteria and is nearest to the HS.

In some embodiments, the LFP search criteria can include one or more of pattern density, polygon size, polygon count, or polygon orientation.

In some embodiments, the pattern density can be the highest pattern density in a search area being imaged by the imaging device, the polygon size can be customizable based on user input and a layer of interest on the printed pattern, the polygon count can be based on the number of polygons in the HS area, or a scan direction of the imaging device can be set to not be parallel to the predominate polygon orientation.

In some embodiments, the determining can further include selecting a search area in the printed pattern for the LFP that does not contain the HS; and scanning the search area with the imaging device for a candidate area that meets the LFP search criteria.

In some embodiments, the method can further include setting the LFP to the candidate area when the candidate area meets the LFP search criteria.

In some embodiments, the method can further include setting the LFP to the candidate area in the search area that best meets the LFP search criteria.

In some embodiments, the search area can form a perimeter around the HS area.

In some embodiments, the field of view of the imaging device can be unchanged such that the candidate area is the same size as the HS area.

In some embodiments, the determining can include: cropping out the HS area within the printed pattern to form a search area for the LFP around a cropped-out HS area; and scanning the search area for a candidate area that meets the LFP search criteria.

In some embodiments, the determining can further include enlarging a field of view of the imaging device to form the search area.

In some embodiments, the method can further include setting the LFP to the candidate area when the candidate area meets the LFP search criteria.

In some embodiments, the method can further include setting the LFP to the candidate area in the search area that best meets the LFP search criteria.

In some embodiments, the determining can include selecting pre-determined search areas for the LFP in the printed pattern where the pre-determined search areas do not contain the HS; and setting the LFP to one of the pre-determined search areas that best meets the LFP search criteria.

In some embodiments, the pre-determined search areas are at corners of the HS area.

In some embodiments, the method can further include further: adjusting a focus of the imaging device used in the imaging of the printed pattern to have the LFP in focus; and imaging the HS area with the imaging device as focused for the LFP.

Other embodiments can include computer-implemented methods performing the method of any of the above embodiments.

In yet other embodiments, a system can include: an imaging device; at least one programmable processor; and a non-transitory computer readable medium having instructions recorded thereon, the instructions when executed by the at least one programmable processor implementing the method of any of the above embodiments.

In some embodiments, the imaging device can be a scanning electron microscope.

Some embodiments can include a non-transitory computer-readable medium that stores a set of instructions that is executable by at least one processor of an apparatus to cause the apparatus to perform a method, the method comprising: determining an area of interest on a printed pattern; obtaining local focus point (LFP) search criteria for searching the printed pattern to determine a LFP for an imaging device; determining the LFP proximate to the area of interest based on the LFP search criteria, the LFP not containing the area of interest.

Other embodiments can include a system comprising: an imaging device; at least one programmable processor; and a non-transitory computer-readable medium that stores a set of instructions that is executable by at least one processor of an apparatus to cause the apparatus to perform a method, the method comprising: determining an area of interest on a printed pattern; obtaining local focus point (LFP) search criteria for searching the printed pattern to determine a LFP for an imaging device; determining the LFP proximate to the area of interest based on the LFP search criteria, the LFP not containing the area of interest.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to some embodiments.

FIG. 2 illustrates an exemplary flow chart for simulating lithography in a lithographic projection apparatus, according to some embodiments.

FIG. 3 schematically depicts an example of imaging device, according to some embodiments.

FIG. 4 schematically illustrates a further example of an imaging device, according to some embodiments.

FIG. 5 illustrates printed pattern having an example of a hot spot and a local focus point, according to some embodiments.

FIG. 6 illustrates a printed pattern having candidate areas for LFPs near a HS, according to some embodiments.

FIG. 7 illustrates an exemplary process for determining an LFP, according to some embodiments.

FIG. 8 illustrates an optimized scanning of a search area for candidate LFP locations, according to some embodiments.

FIG. 9 illustrates selecting an LFP from pre-determined search areas, according to some embodiments.

FIG. 10 illustrates imaging of the HS after selecting an LFP, according to some embodiments.

FIG. 11 illustrates combining the process of FIG. 7 with the additional features of performing HS imaging, according to some embodiments.

FIG. 12 is a block diagram of an example computer system, according to some embodiments.

FIG. 13 is a schematic diagram of a lithographic projection apparatus, according to some embodiments.

FIG. 14 is a schematic diagram of another lithographic projection apparatus, according to some embodiments.

FIG. 15 is a detailed view of the lithographic projection apparatus, according to some embodiments.

FIG. 16 is a detailed view of the source collector module of the lithographic projection apparatus, according to some embodiments.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate: the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

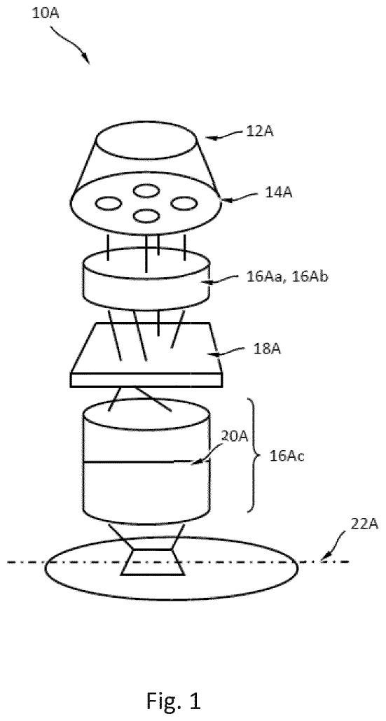

FIG. 1 illustrates a block diagram of various subsystems of a lithographic projection apparatus 10A, according to some embodiments. Major components are a radiation source 12A, which may be a deep-ultraviolet excimer laser source or other type of source including an extreme ultraviolet (EUV) source (as discussed above, the lithographic projection apparatus itself need not have the radiation source), illumination optics which, e.g., define the partial coherence (denoted as sigma) and which may include optics 14A. 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin (Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device, and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1. 0.2. 0.3, etc.) instead of binary value of either 0 or 1. In some embodiments, CTM may be a pixelated gray scale image, where each pixel having values (e.g., within a range [-255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

According to some embodiments of the present disclosure, one or more images may be generated. The images includes various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In some embodiments, the strong and weak signal may be identified based on a selected threshold value. In some embodiments, the threshold value may be fixed (e.g., a midpoint of a highest intensity and a lowest intensity of pixel within the image. In some embodiments, a strong signal may refer to a signal with values greater than or equal to an average signal value across the image and a weak signal may refer to signal with values less than the average signal value. In some embodiments, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present example, derivatives or partial derivative may be determined with respect to each pixel within the image and the values of each pixel may be determined or modified according to a cost function-based evaluation and/or gradient based computation of the cost function. For example, a CTM image may include pixels, where each pixel is a variable that can take any real value.

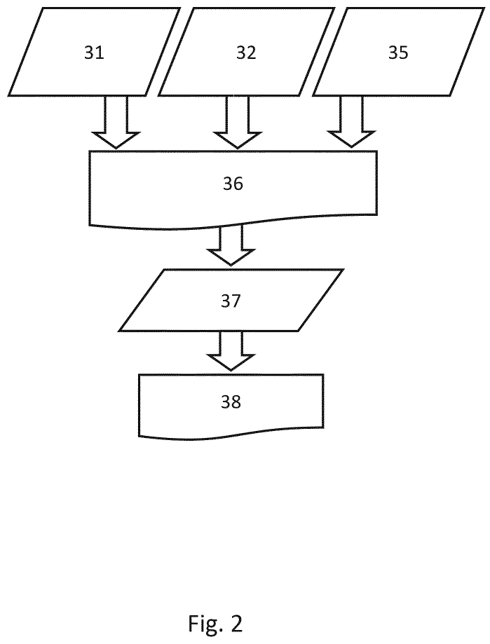

FIG. 2 illustrates an exemplary flow chart for simulating lithography in a lithographic projection apparatus, according to some embodiments. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (σ) settings as well as any particular illumination shape (e.g., off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In some embodiments, a set of clips is extracted, which represents the complicated patterns in the design layout (typically about 50 to 1000 clips, although any number of clips may be used). These patterns or clips represent small portions (i.e. circuits, cells, or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another example, an initial larger set of clips may be extracted from the entire design layout by using some kind of automated (such as machine vision) or manual algorithm that identifies the one or more critical feature areas.

In a lithographic projection apparatus, as an example, a cost function may be expressed as

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) \qquad ( Eq . 1 )$$

where (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process, or the substrate, for instance, focus, CD, image shift, image distortion, image rotation, stochastic variation, throughput, local CD variation, process window, an interlayer characteristic, or a combination thereof. In some embodiments, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In some embodiments, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

When manufacturing a computer chip or other type of integrated circuit, in some cases, extremely small structures are formed on a silicon wafer. These structures can include transistors, which do the “thinking” of the computer chip, and metal wires that are used to connect the transistors. These structures are extremely small, for example, 1000 metal wires placed side by side can fit within the width of a human hair. A computer chip can have several layers of metal wires, one on top of the other, with some layers running primarily in a north/south direction, and other layers running primarily in an cast/west direction. A metal wire on a first layer may be connected to a metal wire on a second layer by a contact hole cut between the two layers that is filled with metal. With the incredibly small dimensions of these wires and contact holes, they must be placed (also referred to as aligned) very precisely, or they will not line up properly. Even the smallest amount of misalignment will cause the connection from the first wire to the second wire via the contact hole metal to fail, which can cause the entire computer chip to fail and become worthless.

Lithography is a process that is involved in the formation of these structures. The quality of a lithography process can be assessed with, for example, a scanning electron microscope (SEM). A SEM can be used to image these extremely small structures, in effect, taking a “picture” of the structures. The image can be used to determine if the structure was formed properly and also if it was formed in the proper location. Again, even small errors in the formation or placement of the structure may cause the computer chip to fail.

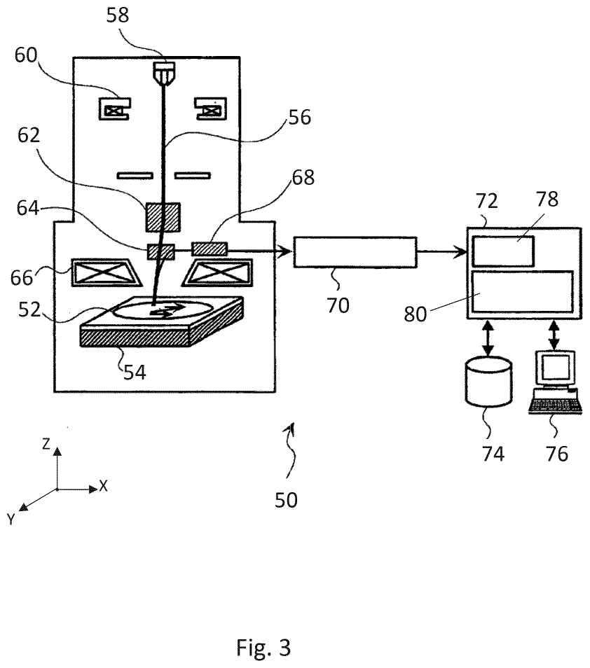

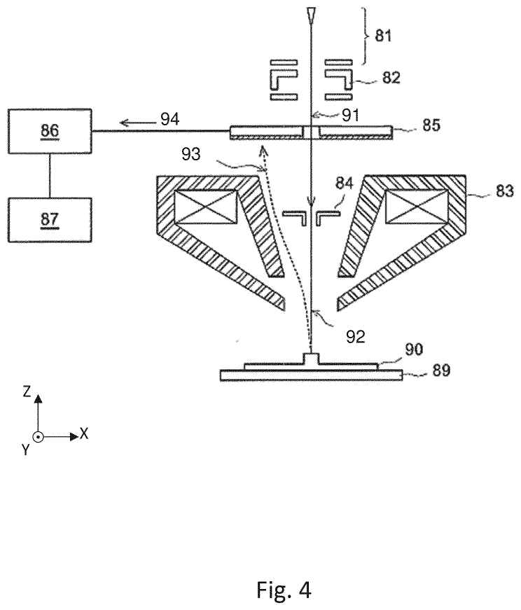

In some embodiments, images of a wafers or other printed patterns can be obtained from an imaging device, for example, a scanning electron microscope (also referred to in some embodiments as an electron beam inspection system). Exemplary embodiments of an imaging device are described in further detail with reference to FIGS. 3 and 4. In some embodiments, the imaging device can have a field of view (FOV) of, for example, up to 8000×8000 pixels, with the pixel size varying from 1 to 10 nm. In some cases, the electron beam inspection system can be similar to a scanning electron microscope but have a large field of view (LFOV) and high throughput for obtaining measured images. In some embodiments, a LFOV can measure, on a side, for example, approximately 1-1000 microns, 100-500 microns, 1-50 microns, 6-12 microns, etc. As used herein, when referring generally to a field of view of an imaging device, this may include any field of view, including the two types discussed above (FOV and LFOV).

FIG. 3 schematically depicts an example of imaging device 50, according to some embodiments. In some embodiments, imaging device 50 may be an electron beam inspection system (e.g., the same as or similar to a scanning electron microscope) that yields an image of a structure on the substrate.

In operation, a primary electron beam 56 emitted from an electron source 58 is converged by condenser lens 60 and then passes through a beam deflector 62, an E×B deflector 64, and an objective lens 66 to irradiate a substrate 52 on a substrate table 54 at a focus. When the substrate 52 is irradiated with electron beam 56, secondary electrons are generated from the substrate 52. The secondary electrons are deflected by the E×B deflector 64 and detected by a secondary electron detector 68. A two-dimensional electron beam image can be obtained by detecting the electrons generated from the sample in synchronization with, e.g., two-dimensional scanning of the electron beam by beam deflector 62 or with repetitive scanning of electron beam 56 by beam deflector 62 in an X or Y direction, together with continuous movement of the substrate 52 by the substrate table 54 in the other of the X or Y direction. Thus, in some embodiments, the electron beam inspection system has a field of view for the electron beam defined by the angular range into which the electron beam can be provided by the electron beam inspection system (e.g., the angular range through which the deflector 62 can provide the electron beam 56). Thus, the spatial extent of the field of the view is the spatial extent to which the angular range of the electron beam can impinge on a surface (wherein the surface can be stationary or can move with respect to the field).

A signal detected by secondary electron detector 68 is converted to a digital signal by an analog/digital (A/D) converter 70, and the digital signal is sent to an image processing system 72. In some embodiments, the image processing system 72 may have memory 78 to store all or part of digital images for processing by a processing unit 80. The processing unit 80 (e.g., specially designed hardware or a combination of hardware and software or a computer readable medium comprising software) is configured to convert or process the digital images into datasets representative of the digital images. In some embodiments, the processing unit 80 is configured or programmed to cause execution of a method described herein. Further, image processing system 72 may have a storage medium 78 configured to store the digital images and corresponding datasets in a reference database. A display device 76 may be connected with the image processing system 72, so that an operator can conduct necessary operation of the equipment with the help of a graphical user interface.

FIG. 4 schematically illustrates a further example of an imaging device, according to some embodiments. The imaging device can be used to inspect a sample 90 (such as a substrate) on a sample stage 88 and comprises a charged particle beam generator 81, a condenser lens module 82, a probe forming objective lens module 83, a charged particle beam deflection module 84, a secondary charged particle detector module 85, and an image forming module 86.

The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 88. In some embodiments, the charged particle beam generator 81, the condenser lens module 82 and the probe forming objective lens module 83, or their equivalent designs, alternatives, or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly forming at least one scanned image. In some embodiments, the secondary charged particle detector module 85 and image forming module 86, or their equivalent designs, alternatives, or any combination thereof, together form an image forming apparatus which forms a scanned image from detected secondary charged particles emitted from sample 90 being bombarded by the charged particle beam probe 92.

In some embodiments, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. So, in some embodiments, the monitoring module 87 is configured or programmed to cause execution of a method described herein. In some embodiments, the monitoring module 87 comprises a computing device. In some embodiments, the monitoring module 87 comprises a computer program to provide functionality herein and encoded on a computer readable medium forming, or disposed within, the monitoring module 87.

As used herein, the term “patterning process” means a process that creates an etched substrate by the application of specified patterns of light as part of a lithography process.

As used herein, the term “target pattern” means an idealized pattern that is to be etched on a substrate.

As used herein, the term “printed pattern” means the physical pattern on a substrate that was etched based on a target pattern. The printed pattern can include, for example, troughs, channels, depressions, edges, or other two- and three-dimensional features resulting from a lithography process.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a resist model (e.g., that models physical effects of the resist, such as chemical effects due to the light), an OPC model (e.g., that can be used to make target patterns and may include sub-resolution resist features (SRAFs), etc.), an imaging device model (e.g., that models what an imaging device may image from a printed pattern).

As used herein, the term “imaging device” means any number or combination of devices and associated computer hardware and software that can be configured to generate images of a target, such as the printed pattern or portions thereof. Non-limiting examples of an imaging devices can include: scanning electron microscopes (SEMs), electron beam inspection systems, x-ray machines, etc.

As used herein, the term “calibrating” means to modify (e.g., improve or tune) and/or validate something, such as the process model.

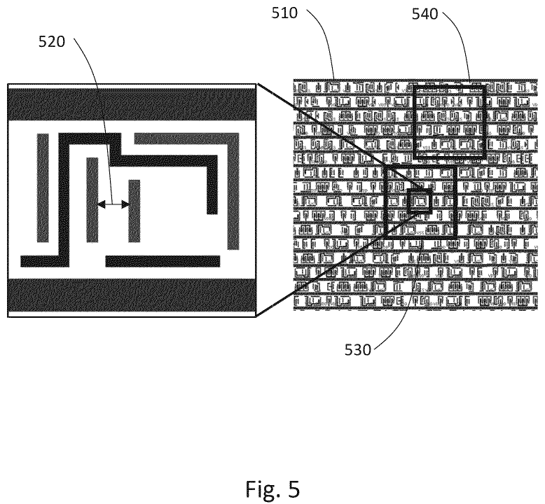

FIG. 5 illustrates printed pattern having an example of a hot spot and a local focus point. An imaging system (e.g., an SEM) can have difficulty guaranteeing that the image (containing HS 520) is well “in focus.” The disclosure provides a new location selection method for the imaging system to adjust focusing prior to imaging. The present disclosure describes systems and methods for imaging a location in a printed pattern that has a very small process window, such a location referred to herein as a “hot spot” (HS). The right portion of FIG. 5 depicts an exemplary printed pattern 510 where in a particular area (shown expanded on the left) there is an area (hot spot area 530) that contains a “hot spot” (HS) 520. A HS is an area or portion thereof where tolerances for deviation from specified dimensions are very small (e.g., as shown in FIG. 5 by the dimension of the HS 520). One technical problem addressed herein is that focusing the imaging device (e.g., an SEM) on the HS location can actually damage or alter the material to an unacceptable degree in this location where the process window is very small. This damage/alteration can occur because some imaging devices (e.g., SEMs) emit an electron beam that damages or alters the printed pattern in the process of imaging. Usually, such “damage” is inconsequential, but in high precision printed patterns, there may be some locations where such damage is impermissible (e.g., overly changing a dimension due to the damage widening a critical distance between two locations, such as a channel width). Apart from possibility of damage (the pattern shape physically changed and/or electrical property altered), the imaging system electron beam can interact with the printed pattern to result in contamination and/or cause a charging effect on the surface of the printed pattern. This can create artifacts on the generated images such as blurring and darkening. Therefore, double imaging on the same areas should be avoided. However, the present disclosure contemplates that some embodiments may incorporate some overlapping (or double imaging) when such may still provide the desired technical effects as disclosed herein. However, in view of the above possible technical drawbacks, some preferred embodiments may include obtaining images only in areas that do not overlap. For example, some image quality parameters and operations can be associated with entire HS area 530. Also, many identical and/or different HS could be found within a HS area 530. Finally, new hotspots may be discovered/detected within HS area 530 with additional imaging processing of the entire HS area. Because, in some cases, hotspots can be very close together on the printed pattern, the imaging device can be controlled to have its FOV be comparatively small (e.g., on the scale of the size of the nearby hotspots). In such cases, there may be little, if any, effective HS area that would permit overlapping when searching for a location to focus the imaging device as described herein.

The disclosed technical solutions provide embodiments that find a suitable area (the “local focus point” (LFP) 540) that is close to or “local” to the HS but does not contain the HS. Presuming that the LFP is at nearly the same height (Z) as the HS location, the imaging device focus can be adjusted (in Z) at the location of LFP rather than at the location of the HS. As this focusing takes time (where electrons are affecting the printed pattern), because the LFP does not include the HS such focusing can be safely performed there without altering this critical structure. Once focus is achieved, the imaging location can then move back to the HS for quick imaging. As described in further detail herein, the LFP can be found by a fine scan around where the HS is or can be quickly done by selecting the best nearby location from a few predefined choices. Various terms relevant to the present disclosure are provided below.

“Local Focus Point” (LFP) means a location that contains portions of a printed pattern suitable for electron beam (EB) focusing, such as by an SEM or any imaging device. The LFP can be used to adjust the EB focal plane prior to HS imaging.

“Local” means generally as close as practicable to an identified hot spot, but the local focus point near the HS not actually containing the HS. “Local” can include immediately adjacent the HS, just outside the viewed area containing the HS (e.g., the HS area), the closest location that meets the search criteria, or any location on the printed pattern that meets the search criteria, where such locations are presumed to likely be somewhat near the hot spot on the basis that the search criteria may only be met in somewhat neighboring areas (i.e., remote areas on the printed pattern are not likely to meet the search criteria).

“Hot Spot” (HS) (or weak point/location) is a location defined based on the user-defined specification. For example, a certain specification (or process window) might only allow 20% or less of changes in a dimension. As another example, the HS can be a location that has the smallest process/yield margin based on a process analysis. Also, a HS condition is not necessarily related to the absolute size of the feature. For example, the distance shown for the HS 520 in FIG. 5 is not the smallest distance between structures that is depicted, but in this example, it is the HS by virtue of that distance being required to be strictly maintained with very little allowed changes.

“HS area” refers to at least a portion of a viewing area of the imaging device that contains a hot spot.

When referring to an LFP “proximate” to a HS area, “proximate” means that the LFP may, in some cases, be the LFP closest to the HS. However, other proximate LFPs may include LFPs that are close enough to provide a sufficiently accurate focus at the HS for the imaging device given the particular application of the imaging device. For example, the LFP may be selected to be the 2^{nd} or 3^{rd} closest possible LFP to the HS as long as it meets the LFP search criteria.

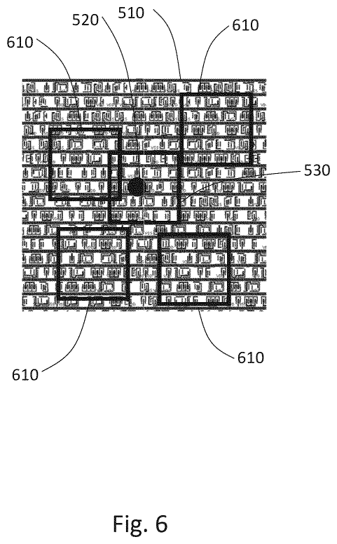

FIG. 6 illustrates a printed pattern having candidate areas for LFPs near a HS. Not every region in a printed pattern is suitable for being an LFP. The present disclosure describes implementations for searching portions of a printed pattern and finding candidate areas that may be suitable for being an LFP. FIG. 6 depicts examples of candidate areas 610 that do not include HS 520. In some cases, a candidate area can at least partially overlap the HS area 530 as long as the candidate area does not contain the HS 520 (e.g., the upper left candidate area 610 in FIG. 6). In some embodiments, candidate areas that do overlap can be excluded from analysis for determining the LFP. In other embodiments, a candidate area can be selected that does not overlap the HS area at all (e.g., the two example candidate areas 610 in the lower portion of FIG. 6). As described further herein, based on search criteria and/or the degree to which a candidate area meets or exceeds the search criteria, one of the candidate areas can be selected to be the LFP.

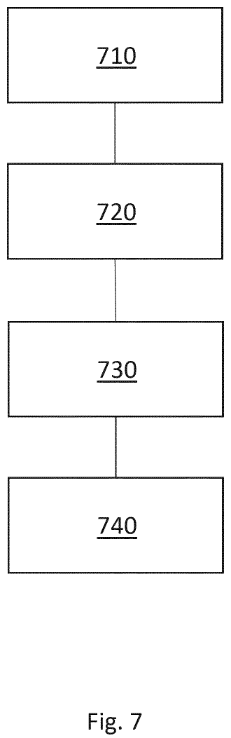

FIG. 7 illustrates an exemplary process for determining an LFP. At 710, the process can include obtaining hot spot location information with respect to a printed pattern. For example, the system may obtain, either automatically or based on user input, a list of HS locations on the printed pattern. Such locations can be in terms of coordinates from a GDS file that describes the structures on the printed pattern. More broadly, the present disclosure contemplates that rather than some embodiments may include determining an area of interest on a printed pattern, which may (or may not) necessarily contain a hot spot. As described below, the present disclosure can thus be utilized for finding local focus points to any area of interest on a printed pattern. Such areas of interest may be specified by a user, obtained by the system reading from a file similar to that described for obtaining hot spot information, etc.

At 720, the process can include obtaining LFP search criteria for searching the printed pattern to determine an LFP for an imaging device. Search criteria are described further herein, but can include, for example, pattern density and/or polygon count for the candidate area. Other parameters that may be set by the system or specified by a user can include a field of view of the imaging device and a search range for where on the printed pattern the disclosed processes can search for candidate areas. Both the field of view and the search range can be specified in GDS coordinates and may be highly process-dependent. Again, the broader disclosure herein contemplates that such LFP search criteria can be utilized for any area of interest.

At 730, the process can include selecting a HS area in the printed pattern that contains a HS. A HS can be, for example, a location on the printed pattern that has a higher failure potential than other locations on the printed pattern. In some embodiments, the HS can be a location determined to have the highest failure potential (e.g., tightest tolerances, smallest process window, etc.) for a given portion of the printed pattern. In other embodiments, a HS can include a location with a failure potential that exceeds a predefined threshold (e.g., a location with a tolerance smaller than a certain value). The HS area can be an area around the HS, but such an area need only contain the HS and thereby need not be any particular size or shape. In certain embodiments, the HS area can be a field of view of the imaging device centered on the HS. In other embodiments, the HS area can be an area highly conformal to the extents of the HS. As before, the broader disclosure herein contemplates embodiments that can include determining the LFP proximate to the area of interest based on the LFP search criteria, the LFP not containing the area of interest.

At 740, the process can include determining the LFP proximate to the HS area based on the LFP search criteria, the LFP not containing the HS. For example, the LFP can be an area on the printed pattern that meets the LFP search criteria and is nearest to the HS. Referring back to FIG. 6, one of the example candidate areas 610 could be set to be the LFP. As described elsewhere herein, the present disclosure provides numerous embodiments for determining the LFP.

In general, the LFP search criteria can specify parameters that will likely result in a focus setting for the imaging device that, when such a focus is used at the HS location, will provide a sufficiently focused image of the HS location. Again, this is because the LFP will be proximate the HS and thereby likely have nearly the same geometric height (Z coordinate) as the HS. To ensure that the candidate areas are both sufficient for focusing and/or representative of the HS, the LFP search criteria can include one or more of pattern density, polygon size, polygon count, or polygon orientation.

Pattern density can be a criterion that can be the highest pattern density in a search area being imaged by the imaging device. Since some features are required to determine whether an image is in focus, there should be a minimum pattern density for the system to discern features to be in or out of focus. Also, since a large number of features can be useful when focusing the imaging device, certain embodiments can search for locations where the pattern density is the highest.

Polygon size can be a criterion that can be customizable based on user input and a layer of interest on the printed pattern. For example, a layer of interest may be one that is predominately long lines in the printed pattern, thus the polygon size in the candidate areas can be similar. Also, in other layers there may be a number of small contact holes around the HS. Accordingly, candidate areas for such can be restricted by the LFP search criteria to be those where the typical size of the features is approximately those of the contact holes.

Polygon count can be a criterion based on the number of polygons in the HS area. For example, if the imaged HS area (based on the FOV of the imaging device) had 1000 polygons (distinct shapes used in the printed pattern, see, e.g., FIG. 5) then the polygon count can be set to approximately the same number of polygons (e.g., +20%). Again, this can help enforce a degree of similarity between candidate areas and the area around the HS that is to be imaged.

Polygon orientation can be a criterion that specifies that a scan direction of the imaging device is set to not be parallel to a predominate polygon orientation. When scanning an EB-based imaging device to generate an image of the printed pattern, the best results may be obtained by scanning in a direction across changes in height. Such height differences can facilitate the identification of edges that can be used for focusing. Accordingly, if an imaging device has a preset scan direction (e.g., in the X direction), but the polygons in a particular area also run in the X direction, then such areas may not be well-suited as candidate areas for an LFP as it could be difficult to determine whether the imaging device is focused.

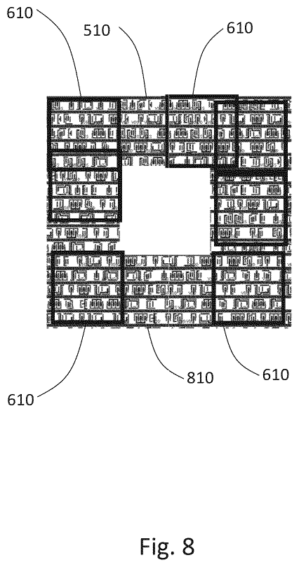

FIG. 8 illustrates an optimized scanning of a search area for candidate LFP locations. While the present disclosure contemplates that there may be numerous equivalent search algorithms that can be utilized to determine the location of an LFP (varying in any number of minor details) two examples of specific implementations are provided herein. One example is depicted in FIG. 8 and referred to herein as “optimized searching.” As previously described, some implementations can include selecting a search area 810 in the printed pattern for the LFP that does not contain the HS. This is depicted by the example of FIG. 8 where the search area around the HS area (not shown in FIG. 8) has been defined. In some embodiments, the search area can form a perimeter around the HS area, which in the example of FIG. 8 is an expanded area based on the size of a field of view of the imaging device. In some embodiments, the field of view of the imaging device can be unchanged such that the candidate area(s) are the same size as the HS area. Such implementations may have the advantage of facilitating the location of LFPs having similar features to that of the HS area (e.g., an area of similar size may have a similar polygon density). Also, maintaining the field of view can simplify control requirements and provide a known search area such as when the search area is an immediate perimeter around the HS area. The searching algorithm can then scan the search area with the imaging device for a candidate area (e.g., candidate area(s) 610) that meets the LFP search criteria. The scanning can include taking a very fine steps that consider a large number of areas in the search area. For example, the search area can have dozens, hundreds, or even thousands of candidate areas that can be LFPs, with the algorithm incrementally stepping through them, randomly selecting from them, etc. Because such an exhaustive search generally finds the optimal location to achieve the best focus, it is referred to as “optimized searching.”

Depending on the embodiments, different conditions for setting a given candidate area to be the LFP can be implemented. For example, setting the LFP to the candidate area can occur when the candidate area meets the LFP search criteria. This technique can reduce processing time/increase throughput by taking the first acceptable candidate area found. In other embodiments, setting the LFP to the candidate area in the search area can be based on the candidate area that best meets the LFP search criteria. In contrast to the previous example, the technique of finding the best match can take a detailed view of many possible areas in the search area to identify potentially a large number of candidate areas. From those candidate areas, the one that best meets the search criteria (e.g., has the highest number of polygons, the proper orientation, etc.) may be selected to be set as the LFP. While such a technique may provide the best results (sharpest and/or most accurate eventual focus for the HS), it can also result in higher computational overhead and/or cause reduced throughput compared to other, faster techniques.

In some embodiments, the search area can be defined based on performing a cropping operation on a GDS file (or equivalent digital replica) of the printed pattern to remove the HS area. While similar to the example described above, the prior example did not necessarily require removal of the HS area from a replicated printed pattern. In some exemplary embodiments, such a process can include cropping out the HS area within the printed pattern to form a search area for the LFP around a cropped-out HS area and scanning the search area for a candidate area that meets the LFP search criteria.

Similar to the embodiments described above, the process can further include enlarging a field of view of the imaging device to form the search area. Similar to the above, some implementations can include setting the LFP to the candidate area when the candidate area meets the LFP search criteria or setting the LFP to the candidate area in the search area that best meets the LFP search criteria.

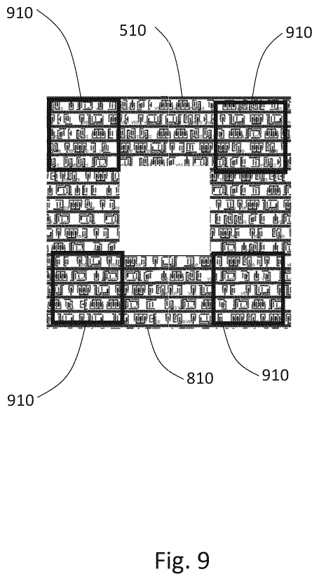

FIG. 9 illustrates selecting an LFP from pre-determined search areas. In some embodiments, rather than performing an exhaustive scan of a search area 810 for candidate LFPs, predefined search areas 910 can be utilized. For example, such embodiments can include selecting pre-determined search areas for the LFP in the printed pattern where the pre-determined search areas do not contain the HS. The process can include setting the LFP to one of the pre-determined search areas that best meets the LFP search criteria. One example of predefined search areas is depicted in FIG. 9 where the pre-determined search areas 910 are at corners of the HS area (not shown). Other embodiments can include where the predetermined search areas are in the centers of the sides of the HS area, or generally can be at any locations on the printed pattern that are determined ahead of time to be candidate areas rather than searched for.

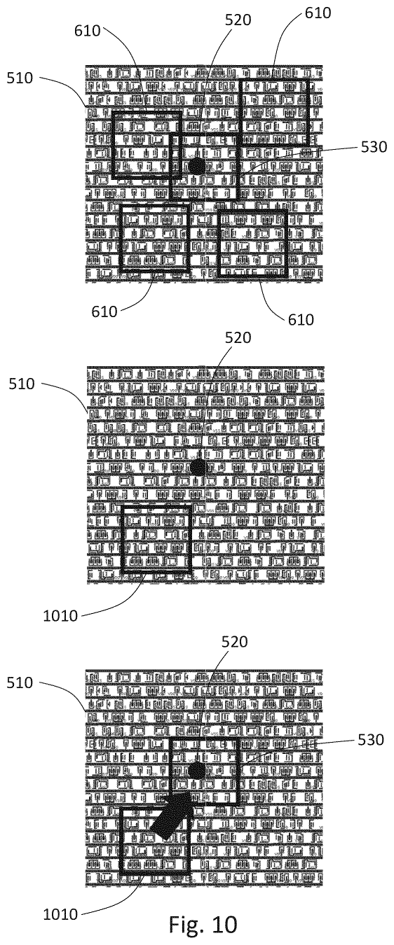

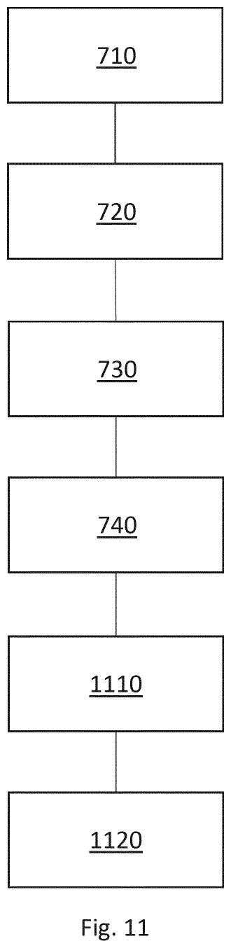

FIG. 10 illustrates imaging of the HS after selecting an LFP. FIG. 11 illustrates a process combining the process of FIG. 5 with the additional features of performing HS imaging. FIG. 10 summarizes the prior disclosure relating to locating candidate LFP locations based on searching areas that do not contain a HS, selecting one candidate area to be set to the LFP, and imaging the HS utilizing the focus obtained for the imaging device when viewing the LFP.

The top panel in FIG. 10 depicts a printed pattern 510 having a HS 520 in a HS area 530. Candidate areas 610 for LFPs are shown at several exemplary locations, which may be either from scanning a specified search area (e.g., similar to that shown in FIG. 8) or may be pre-selected candidate areas (e.g., similar to that shown in FIG. 9).

The middle panel in FIG. 10 depicts the selection of one of the candidate areas 610 to be the LFP 1010. The selection of LFP 1010 can be based on any of the disclosed searching criteria herein. Again, the LFP 1010 does not include HS 520.

The bottom panel in FIG. 10 depicts imaging of the HS 520. As previously mentioned, certain embodiments can include adjusting a focus of the imaging device used in the imaging of the printed pattern to have the LFP in focus. For example, once LFP 1010 is set, the focal plane of the imaging device can be varied until the image of the printed pattern at the LFP is sharpest. Once this focus is determined, the process can then include controlling the imaging device to perform imaging the HS area 530 with the imaging device as focused for the LFP. This is depicted by the arrow showing that the scanning location can be controlled to move from the LFP 1010 to the HS area 530. Again, by performing the focusing procedure at the LFP, which is away from the HS but in a region selected to accurately represent the area around the HS, damage/alteration to the HS from the electron beam of the imaging device can be minimized.

FIG. 11 illustrates combining the process of FIG. 7 with the additional features of performing HS imaging. The depicted process includes elements 710-740, describing an exemplary method of determining an LFP. Additionally, FIG. 11 includes, at 1110, the method described in FIG. 10 of adjusting a focus of the imaging device used in the imaging of the printed pattern to have the LFP in focus. Also, at 1120, the process can include imaging the HS area 530 with the imaging device as focused for the LFP. Accordingly, while it is contemplated that various processes can include actually imaging the HS, such is not necessary as indicated by the separate embodiments of FIG. 7 and FIG. 11.

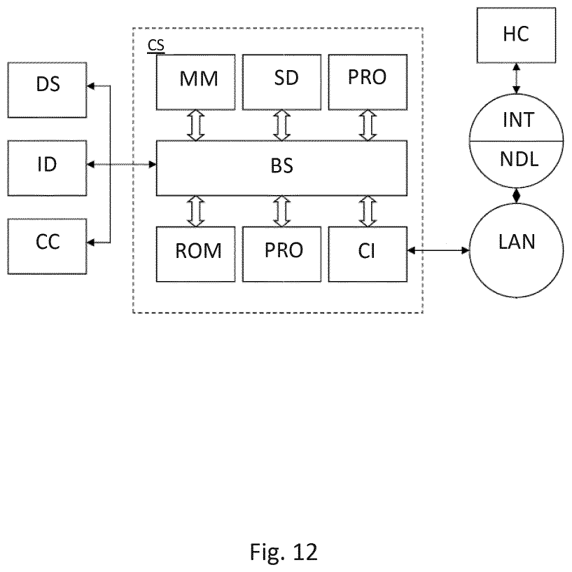

FIG. 12 is a block diagram of an example computer system CS, according to some embodiments.

Computer system CS includes a bus BS or other communication mechanism for communicating information, and a processor PRO (or multiple processor) coupled with bus BS for processing information. Computer system CS also includes a main memory MM, such as a random-access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative example, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

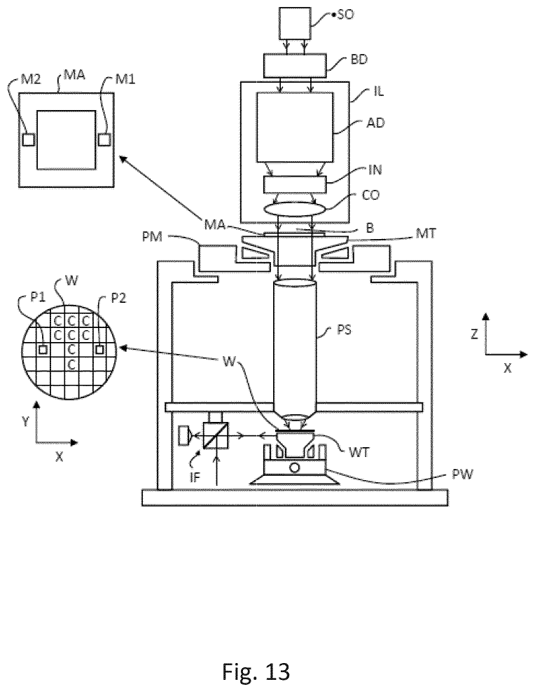

FIG. 13 is a schematic diagram of a lithographic projection apparatus, according to some embodiments.

The lithographic projection apparatus can include an illumination system IL, a first object table MT, a second object table WT, and a projection system PS.

Illumination system IL can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as o-outer and o-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g., so as to position different target portions C in the path of beam PB. Similarly, the first positioning apparatus can be used to accurately position patterning device MA with respect to the path of beam B. e.g., after mechanical retrieval of the patterning device MA from a patterning device library, or during a scan. In general, movement of the object tables MT. WT can be realized with the aid of a long-stroke module (coarse positioning) and a short-stroke module (fine positioning). However, in the case of a stepper (as opposed to a step-and-scan tool) patterning device table MT may just be connected to a short stroke actuator or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

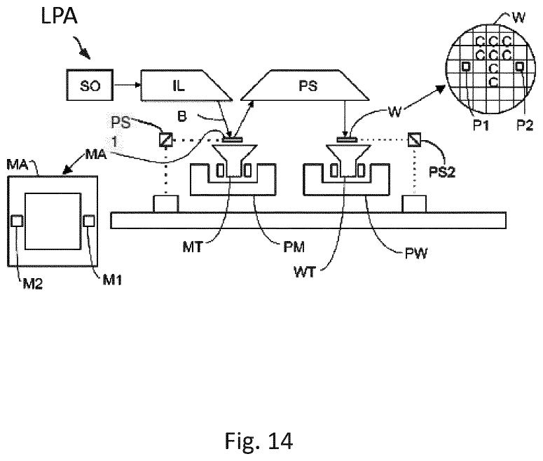

FIG. 14 is a schematic diagram of another lithographic projection apparatus (LPA), according to some embodiments.

LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g., a mask or a reticle) MA and connected to a first positioner PM configured to accurately position the patterning device;

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40-layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as o-outer and o-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometrie device, linear encoder, or capacitive sensor), the substrate table WT can be moved accurately, e.g., so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g., patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e. a single dynamic exposure). The velocity and direction of substrate table WT relative to the support structure (e.g., patterning device table) MT may be determined by the (de-) magnification and image reversal characteristics of the projection system PS.

In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

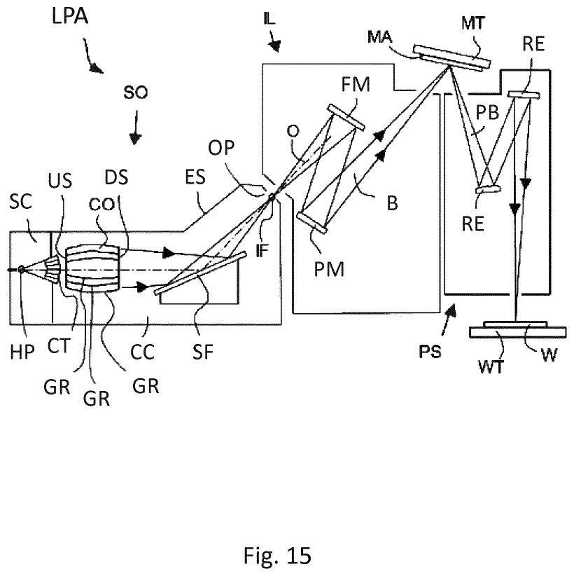

FIG. 15 is a detailed view of the lithographic projection apparatus, according to some embodiments.

As shown, LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device pm arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

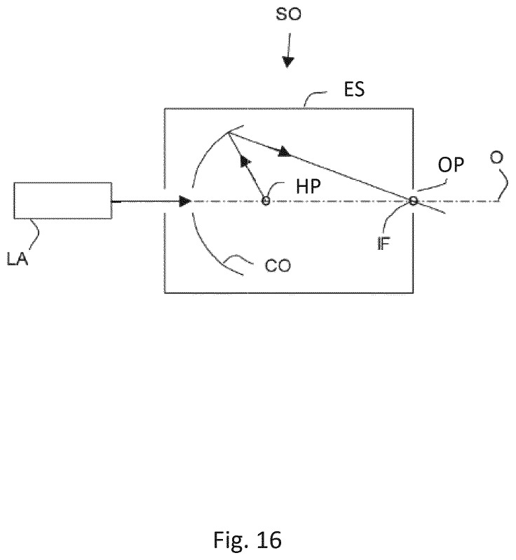

FIG. 16 is a detailed view of source collector module SO of lithographic projection apparatus LPA, according to some embodiments.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Further embodiments are disclosed in the subsequent list of numbered clauses:
1. A non-transitory computer-readable medium that stores a set of instructions that is executable by at least one processor of an apparatus to cause the apparatus to perform a method, the method comprising: obtaining hot spot (HS) location information with respect to a printed pattern; obtaining LFP search criteria for searching the printed pattern to determine a local focus point (LFP) for an imaging device; selecting a HS area in the printed pattern that contains a HS; and determining the LFP proximate to the HS area based on the LFP search criteria, the LFP not containing the HS.
2. The computer-readable medium as in any of the preceding clauses, wherein the HS is a location on the printed pattern that has a higher failure potential than other locations on the printed pattern.
3. The computer-readable medium as in any of the preceding clauses, wherein the LFP is an area on the printed pattern that meets the LFP search criteria and is nearest to the HS.
4. The computer-readable medium as in any of the preceding clauses, wherein the LFP search criteria comprises one or more of pattern density, polygon size, polygon count, or polygon orientation.
5. The computer-readable medium as in any of the preceding clauses, wherein the pattern density is the highest pattern density in a search area being imaged by the imaging device.
6. The computer-readable medium as in any of the preceding clauses, wherein the polygon size is customizable based on user input and a layer of interest on the printed pattern.
7. The computer-readable medium as in any of the preceding clauses, wherein the polygon count is based on the number of polygons in the HS area.
8. The computer-readable medium as in any of the preceding clauses, wherein a scan direction of the imaging device is set to not be parallel to the predominate polygon orientation.
9. The computer-readable medium as in any of the preceding clauses, the determining further comprising: selecting a search area in the printed pattern for the LFP that does not contain the HS; and scanning the search area with the imaging device for a candidate area that meets the LFP search criteria.
10. The computer-readable medium as in any of the preceding clauses, the method further comprising setting the LFP to the candidate area when the candidate area meets the LFP search criteria.
11. The computer-readable medium as in any of the preceding clauses, the method further comprising setting the LFP to the candidate area in the search area that best meets the LFP search criteria.
12. The computer-readable medium as in any of the preceding clauses, wherein the search area forms a perimeter around the HS area.
13. The computer-readable medium as in any of the preceding clauses, wherein the field of view of the imaging device is unchanged such that the candidate area is the same size as the HS area.
14. The computer-readable medium as in any of the preceding clauses, the determining comprising: cropping out the HS area within the printed pattern to form a search area for the LFP around a cropped-out HS area; and scanning the search area for a candidate area that meets the LFP search criteria.
15. The computer-readable medium as in any of the preceding clauses, the determining further comprising enlarging a field of view of the imaging device to form the search area.
16. The computer-readable medium as in any of the preceding clauses, the method further comprising setting the LFP to the candidate area when the candidate area meets the LFP search criteria.
17. The computer-readable medium as in any of the preceding clauses, the method further comprising setting the LFP to the candidate area in the search area that best meets the LFP search criteria.
18. The computer-readable medium as in any of the preceding clauses, the determining comprising: selecting pre-determined search areas for the LFP in the printed pattern where the pre-determined search areas do not contain the HS; and setting the LFP to one of the pre-determined search areas that best meets the LFP search criteria.
19. The computer-readable medium as in any of the preceding clauses, wherein the pre-determined search areas are at corners of the HS area.
20. The computer-readable medium as in any of the preceding clauses, the method further comprising: adjusting a focus of the imaging device used in the imaging of the printed pattern to have the LFP in focus; and imaging the HS area with the imaging device as focused for the LFP.
21. A computer-implemented method comprising: obtaining hot spot (HS) location information with respect to a printed pattern; obtaining LFP search criteria for searching the printed pattern to determine a local focus point (LFP) for an imaging device; selecting a HS area in the printed pattern that contains a HS; and determining the LFP proximate to the HS area based on the LFP search criteria, the LFP not containing the HS.
22. The method as in any of the preceding clauses, wherein the HS is a location on the printed pattern that has a higher failure potential than other locations on the printed pattern.
23. The method as in any of the preceding clauses, wherein the LFP is an area on the printed pattern that meets the LFP search criteria and is nearest to the HS.
24. The method as in any of the preceding clauses, wherein the LFP search criteria comprises one or more of pattern density, polygon size, polygon count, or polygon orientation.
25. The method as in any of the preceding clauses, wherein the pattern density is the highest pattern density in a search area being imaged by the imaging device.
26. The method as in any of the preceding clauses, wherein the polygon size is customizable based on user input and a layer of interest on the printed pattern.
27. The method as in any of the preceding clauses, wherein the polygon count is based on the number of polygons in the HS area.
28. The method as in any of the preceding clauses, wherein a scan direction of the imaging device is set to not be parallel to the predominate polygon orientation.
29. The method as in any of the preceding clauses, the determining further comprising: selecting a search area in the printed pattern for the LFP that does not contain the HS; and scanning the search area with the imaging device for a candidate area that meets the LFP search criteria.
30. The method as in any of the preceding clauses, the method further comprising setting the LFP to the candidate area when the candidate area meets the LFP search criteria.
31. The method as in any of the preceding clauses, the method further comprising setting the LFP to the candidate area in the search area that best meets the LFP search criteria.
32. The method as in any of the preceding clauses, wherein the search area forms a perimeter around the HS area.
33. The method as in any of the preceding clauses, wherein the field of view of the imaging device is unchanged such that the candidate area is the same size as the HS area.
34. The method as in any of the preceding clauses, the determining comprising: cropping out the HS area within the printed pattern to form a search area for the LFP around a cropped-out HS area; and scanning the search area for a candidate area that meets the LFP search criteria.
35. The method as in any of the preceding clauses, the determining further comprising enlarging a field of view of the imaging device to form the search area.
36. The method as in any of the preceding clauses, the method further comprising setting the LFP to the candidate area when the candidate area meets the LFP search criteria.
37. The method as in any of the preceding clauses, the method further comprising setting the LFP to the candidate area in the search area that best meets the LFP search criteria.
38. The method as in any of the preceding clauses, the determining comprising: selecting pre-determined search areas for the LFP in the printed pattern where the pre-determined search areas do not contain the HS; and setting the LFP to one of the pre-determined search areas that best meets the LFP search criteria.
39. The method as in any of the preceding clauses, wherein the pre-determined search areas are at corners of the HS area.
40. The method as in any of the preceding clauses, the method further comprising: adjusting a focus of the imaging device used in the imaging of the printed pattern to have the LFP in focus; and imaging the HS area with the imaging device as focused for the LFP.
41. A system comprising: an imaging device; at least one programmable processor; and a non-transitory computer-readable medium that stores a set of instructions that is executable by at least one processor of an apparatus to cause the apparatus to perform a method, the method comprising: obtaining hot spot (HS) location information with respect to a printed pattern; obtaining LFP search criteria for searching the printed pattern to determine a local focus point (LFP) for an imaging device; selecting a HS area in the printed pattern that contains a HS; and determining the LFP proximate to the HS area based on the LFP search criteria, the LFP not containing the HS.
42. The system as in any of the preceding clauses, wherein the HS is a location on the printed pattern that has a higher failure potential than other locations on the printed pattern.
43. The system as in any of the preceding clauses, wherein the LFP is an area on the printed pattern that meets the LFP search criteria and is nearest to the HS.
44. The system as in any of the preceding clauses, wherein the LFP search criteria comprises one or more of pattern density, polygon size, polygon count, or polygon orientation.
45. The system as in any of the preceding clauses, wherein the pattern density is the highest pattern density in a search area being imaged by the imaging device.
46. The system as in any of the preceding clauses, wherein the polygon size is customizable based on user input and a layer of interest on the printed pattern.
47. The system as in any of the preceding clauses, wherein the polygon count is based on the number of polygons in the HS area.
48. The system as in any of the preceding clauses, wherein a scan direction of the imaging device is set to not be parallel to the predominate polygon orientation.
49. The system as in any of the preceding clauses, the determining further comprising: selecting a search area in the printed pattern for the LFP that does not contain the HS; and scanning the search area with the imaging device for a candidate area that meets the LFP search criteria.
50. The system as in any of the preceding clauses, the method further comprising setting the LFP to the candidate area when the candidate area meets the LFP search criteria.
51. The system as in any of the preceding clauses, the method further comprising setting the LFP to the candidate area in the search area that best meets the LFP search criteria.
52. The system as in any of the preceding clauses, wherein the search area forms a perimeter around the HS area.
53. The system as in any of the preceding clauses, wherein the field of view of the imaging device is unchanged such that the candidate area is the same size as the HS area.
54. The system as in any of the preceding clauses, the determining comprising: cropping out the HS area within the printed pattern to form a search area for the LFP around a cropped-out HS area; and scanning the search area for a candidate area that meets the LFP search criteria.
55. The system as in any of the preceding clauses, the determining further comprising enlarging a field of view of the imaging device to form the search area.
56. The system as in any of the preceding clauses, the method further comprising setting the LFP to the candidate area when the candidate area meets the LFP search criteria.
57. The system as in any of the preceding clauses, the method further comprising setting the LFP to the candidate area in the search area that best meets the LFP search criteria.
58. The system as in any of the preceding clauses, the determining comprising: selecting pre-determined search areas for the LFP in the printed pattern where the pre-determined search areas do not contain the HS; and setting the LFP to one of the pre-determined search areas that best meets the LFP search criteria.
59. The system as in any of the preceding clauses, wherein the pre-determined search areas are at corners of the HS area.
60. The system as in any of the preceding clauses, the method further comprising: adjusting a focus of the imaging device used in the imaging of the printed pattern to have the LFP in focus; and imaging the HS area with the imaging device as focused for the LFP.
61. The system as in any of the preceding clauses, wherein the imaging device is a scanning electron microscope.
62. A non-transitory computer-readable medium that stores a set of instructions that is executable by at least one processor of an apparatus to cause the apparatus to perform a method, the method comprising: determining an area of interest on a printed pattern; obtaining local focus point (LFP) search criteria for searching the printed pattern to determine a LFP for an imaging device; determining the LFP proximate to the area of interest based on the LFP search criteria, the LFP not containing the area of interest.
63. A system comprising: an imaging device; at least one programmable processor; and a non-transitory computer-readable medium that stores a set of instructions that is executable by at least one processor of an apparatus to cause the apparatus to perform a method, the method comprising: determining an area of interest on a printed pattern; obtaining local focus point (LFP) search criteria for searching the printed pattern to determine a LFP for an imaging device; determining the LFP proximate to the area of interest based on the LFP search criteria, the LFP not containing the area of interest.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A non-transitory computer-readable medium that stores a set of instructions that is executable by at least one processor of an apparatus to cause the apparatus to perform operations comprising:
obtaining hot spot (HS) location information with respect to a printed pattern;
obtaining local focus point (LFP) search criteria for searching the printed pattern to determine a LFP for an imaging device;
selecting a HS area in the printed pattern that contains a HS; and
determining the LFP proximate to the HS area based on the LFP search criteria, the LFP not containing the HS.

2. The computer-readable medium of claim 1, wherein the HS is a location on the printed pattern that has a higher failure potential than other locations on the printed pattern.

3. The computer-readable medium of claim 1, wherein the LFP is an area on the printed pattern that meets the LFP search criteria and is nearest to the HS.

4. The computer-readable medium of claim 1, wherein the LFP search criteria comprises one or more of pattern density, polygon size, polygon count, or polygon orientation.

5. The computer-readable medium of claim 4, wherein the pattern density is the highest pattern density in a search area being imaged by the imaging device.

6. The computer-readable medium of claim 4, wherein the polygon size is customizable based on user input and a layer of interest on the printed pattern.

7. The computer-readable medium of claim 4, wherein the polygon count is based on a number of polygons in the HS area.

8. The computer-readable medium of claim 4, wherein a scan direction of the imaging device is set to not be parallel to a predominate polygon orientation.

9. The computer-readable medium of claim 1, the determining further comprising:
selecting a search area in the printed pattern for the LFP that does not contain the HS; and
scanning the search area with the imaging device for a candidate area that meets the LFP search criteria.

10. The computer-readable medium of claim 9, the operations further comprising setting the LFP to the candidate area when the candidate area meets the LFP search criteria.

11. The computer-readable medium of claim 9, the operations further comprising setting the LFP to the candidate area in the search area that best meets the LFP search criteria.

12. The computer-readable medium of claim 9, wherein the search area forms a perimeter around the HS area.

13. The computer-readable medium of claim 9, wherein a field of view of the imaging device is unchanged such that the candidate area is the same size as the HS area.

14. The computer-readable medium of claim 1, the determining comprising:
cropping out the HS area within the printed pattern to form a search area for the LFP around a cropped-out HS area; and
scanning the search area for a candidate area that meets the LFP search criteria.

15. A system comprising:
an imaging device;
at least one programmable processor; and
a non-transitory computer-readable medium that stores a set of instructions that is executable by at least one processor of the system to cause the system to perform operations comprising:
determining an area of interest on a printed pattern;
obtaining local focus point (LFP) search criteria for searching the printed pattern to determine a LFP for an imaging device;
determining the LFP proximate to the area of interest based on the LFP search criteria, the LFP not containing the area of interest.

16. A system comprising:
an imaging device;
at least one programmable processor; and
a non-transitory computer-readable medium that stores a set of instructions that is executable by at least one processor of the system to cause the system to perform operations comprising:
obtaining hot spot (HS) location information with respect to a printed pattern;
obtaining LFP search criteria for searching the printed pattern to determine a local focus point (LFP) for an imaging device;
selecting a HS area in the printed pattern that contains a HS; and
determining the LFP proximate to the HS area based on the LFP search criteria, the LFP not containing the HS.

17. The system of claim 16, wherein the HS is a location on the printed pattern that has a higher failure potential than other locations on the printed pattern.

18. The system of claim 16, wherein the LFP is an area on the printed pattern that meets the LFP search criteria and is nearest to the HS.

19. The system of claim 16, wherein the LFP search criteria comprises one or more of pattern density, polygon size, polygon count, or polygon orientation.

20. The system of claim 19, wherein the pattern density is the highest pattern density in a search area being imaged by the imaging device.
